(19) United States
(12) Patent Application Publication
(10) Pub. No.: US 2016/0240377 A1
(43) Pub. Date: Aug. 18, 2016

(54) METHOD OF DEFINING POLY-SILICON GROWTH DIRECTION

(71) Applicant: SHENZHEN CHINA STAR OPTOELECTRONICS TECHNOLOGY CO., LTD., Guangdong (CN)

(72) Inventors: Wei YU, Shenzhen, Guangdong (CN); Yewen WANG, Shenzhen, Guangdong (CN); Yungjui LEE, Shenzhen, Guangdong (CN)

(73) Assignee: Shenzhen China Star Optoelectronics Technology Co., Ltd., Shenzhen, Guangdong (CN)

(21) Appl. No.: 14/381,933

(22) PCT Filed: Jul. 14, 2014
(86) PCT No.: PCT/CN2014/082132

§ 371 Date: Aug. 28, 2014

(30) Foreign Application Priority Data
Jun. 25, 2014 (CN) 201410294517.6

(51) Int. Cl. H01L 21/02

(52) U.S. Cl. CPC H01L 21/02675; H01L 21/02595; H01L 21/02532; H01L 21/02422; H01L 21/02661; H01L 21/02502; H01L 21/02658; H01L 21/0262

(57) ABSTRACT

The present invention provides a method of defining poly-silicon growth direction, comprising: providing a glass substrate (1); forming a buffer layer (3) on the glass substrate (1); forming a metal film layer (5) on the buffer layer (3); implementing etching to the metal film layer (5) to form a metal film array (51); covering the buffer layer (3) with a high-purity quartz mask (7); forming a graphene layer (9) on the high-purity quartz mask (7) and the metal film array (51); implementing etching to the graphene layer (9) to form a graphene layer array (91); forming an amorphous silicon thin film (2) on the buffer layer (3); implementing high temperature dehydrogenation to the amorphous silicon thin film (2); implementing an Excimer laser anneal process to the amorphous silicon thin film (2); melted amorphous silicon is re-crystallized.

### FIELD OF THE INVENTION

The present invention relates to a skill field of display, and more particularly to a method of defining poly-silicon growth direction.

### BACKGROUND OF THE INVENTION

With the development of the flat panel displays, the panels with higher resolutions and lower power consumption are constantly required. Because the Low Temperature Poly-Silicon (LTPS) possess high electron mobility, the industry attaches importance to it in the Liquid Crystal Display (LCD) and Organic Light Emitting Diode (OLED) skill fields. The LPTS is considered as an important material for realizing low cost, full color flat panel displays. For a flat panel display, the Low Temperature Poly-Silicon has many advantages such as high resolution, fast response rate, high brightness, high aperture ratio, low power consumption and etc. Meanwhile, the Low Temperature Poly-Silicon can be produced under low temperature environment and with the capability of manufacturing the C-MOS (Complementary Metal Oxide Semiconductor) circuit, the Low Temperature Poly-Silicon is widely discussed for meeting the requirement of high resolution and low power consumption.

The Low Temperature Poly-Silicon (LTPS) is a branch of Poly-Silicon technology. The arrangement of the molecule structure of the Poly-Silicon in a crystal grain is regular and directional. Therefore, the electron mobility is 200-300 times of the amorphous silicon (a-Si) which is arranged in disorder the response rate of the flat panel display can be enormously promoted. In the initial developing stages of the Poly-Silicon technology, A Laser anneal process, which is a high temperature oxidation process is necessary for transferring the structure of the glass substrate from amorphous silicon (a-Si) into Poly-Silicon. Then, High Temperature Poly-Silicon (HTPS) can be obtained. In this moment, the temperature of the glass substrate can reach over 1000 degree C. In comparison with the traditional High Temperature Poly-Silicon, the laser exposure process is still required for the Low Temperature Poly-Silicon, thought. Nevertheless, an Excimer laser is employed as being the heat source. After the laser is conducted through the transmission system, a laser beam with uniformly distributed energy is projected on the glass substrate with amorphous silicon structure. After the glass substrate with amorphous silicon structure absorbs the energy of the Excimer laser, the glass substrate is then transferred into Poly-Silicon structure substrate. The whole process is accomplished under 600 degrees Celsius. Any normal glass substrates can bare such temperature which enormously reduces the manufacture cost. Beside reduction of the manufacture cost, the Low Temperature Poly-Silicon technology further provides more merits: higher electron mobility, better stability.

At present, several methods for producing the Low Temperature Poly-Silicon can be illustrated, such as Solid Phase Crystallization (SPC), Metal-Induced Crystallization (MIC) and Excimer Laser Anneal (ELA), among which Excimer laser anneal (ELA) is the most widely used and developed method nowadays. The method mainly comprises: first, a buffer layer is grown on a glass, and then, the amorphous silicon is grown thereon. After the high temperature dehydrogenation, the laser of the ELA scans the amorphous silicon to implement Excimer laser anneal. The amorphous silicon absorbs the energy of the laser and melts in an extremely short time and reach up at a very high temperature. Ultimately, the amorphous silicon cools down to be re-crystallized into Poly-Silicon.

The grain size of the Low Temperature Poly-Silicon possesses quite significant effect to the electricity of the Poly-Silicon. During the ELA process, the amorphous silicon suffered with the high temperature and nearly completely melts. Then, the re-crystallization into Poly-Silicon of the amorphous silicon accomplished. As being re-crystallized, the occurrence of crystallization follows the direction from low energy toward high energy, i.e. from the low temperature area toward the high temperature area. In prior arts, the amorphous silicon layer is formed directly on the buffer layer. During the process of Excimer laser anneal, the heated conditions of the respective areas of the amorphous silicon layer reach unanimity and no temperature gradients exist. Consequently, the start point and the direction of crystallization are in a mess. The grain size is too small and too many grain boundaries appear. Accordingly, electron mobility of the Poly-Silicon is affected and the response rate of the flat panel display can be significantly impacted.

### SUMMARY OF THE INVENTION

An objective of the present invention is to provide a method of defining poly-silicon growth direction capable of defining and controlling the growth direction of the poly-silicon as being formed. Accordingly, the electron mobility of the poly-silicon is promoted and the response rate of the flat panel display can be raised.

For realizing the aforesaid objective, the present invention provides a method of defining poly-silicon growth direction, comprising steps of:

step 1, providing a glass substrate and cleaning the glass substrate;

step 2, forming a buffer layer on the glass substrate;

step 3, forming a metal film layer on the buffer layer;

step 4, implementing etching to the metal film layer with an acid liquid to form a metal film array;

step 5, covering an area of the buffer layer outside the metal film array with a high-purity quartz mask to expose the metal film array;

step 6, forming a graphene layer on the high-purity quartz mask and the metal film array;

step 7, implementing etching to the graphene layer to form a graphene layer array coinciding with the metal film array of the fourth step;

step 8, forming an amorphous silicon thin film on the buffer layer having the metal film array and the graphene layer array;

step 9, implementing high temperature dehydrogenation to the amorphous silicon thin film;

step 10, implementing an Excimer laser anneal process to the amorphous silicon thin film, and the amorphous silicon thin film melts after absorbing the energy of the laser and temperature rising;

step 11, melted amorphous silicon is re-crystallized and starts growing and becomes larger from a low temperature area comprising the metal film array and the graphene layer array toward high temperature areas around to form poly-silicon.

The buffer layer in step 2 comprises two portions, one portion near the glass substrate is amorphous silicon nitride SiNx, and the other portion relatively far from the glass substrate is silicon oxide SiOx, and the SiOx is on the SiNx.

The metal film layer in step 3 is formed by PVD physical vapor deposition metal coating.

A thickness of the metal film layer in step 3 is 10-500 nm.

A material of the metal film layer is one or more of copper Cu, nickel Ni, gold Au, platinum Pt, iron Fe, molybdenum Mo, aluminum Al, and the purity≧99.9%.

In step 6, a thickness of the graphene layer is 0.35-20 nm.

In step 6, the graphene layer is formed by low-temp chemical vapor deposition graphene coating with hydrocarbons as a source of carbon.

The process conditions of the chemical vapor deposition are: the pressure is 5 Pa-5 kPa, and the temperature is 400-680 degrees Celsius.

In step 7, the etching to the graphene layer is implemented by laser etching or dry etching.

The positions of the metal film array and the graphene layer array are located near a channel.

The present invention further provides a method of defining poly-silicon growth direction, comprising steps of:

step 1, providing a glass substrate and cleaning the glass substrate;

step 2, forming a buffer layer on the glass substrate;

step 3, forming a metal film layer on the buffer layer;

step 4, implementing etching to the metal film layer with an acid liquid to form a metal film array;

step 5, covering an area of the buffer layer outside the metal film array with a high-purity quartz mask to expose the metal film array;

step 6, forming a graphene layer on the high-purity quartz mask and the metal film array;

step 7, implementing etching to the graphene layer to form a graphene layer array coinciding with the metal film array of the fourth step;

step 8, forming an amorphous silicon thin film on the buffer layer having the metal film array and the graphene layer array;

step 9, implementing high temperature dehydrogenation to the amorphous silicon thin film;

step 10, implementing an Excimer laser anneal process to the amorphous silicon thin film, and the amorphous silicon thin film melts after absorbing the energy of the laser and temperature rising;

step 11, melted amorphous silicon is re-crystallized and starts growing and becomes larger from a low temperature area comprising the metal film array and the graphene layer array toward high temperature areas around to form poly-silicon;

the buffer layer in step 2 comprises two portions, one portion near the glass substrate is amorphous silicon nitride SiNx, and the other portion relatively far from the glass substrate is silicon oxide SiOx, and the SiOx is on the SiNx;

the metal film layer in step 3 is formed by PVD physical vapor deposition metal coating;

a thickness of the metal film layer in step 3 is 10-500 nm; a material of the metal film layer is one or more of copper Cu, nickel Ni, gold Au, platinum Pt, iron Fe, molybdenum Mo, aluminum Al, and the purity≧99.9%;

in step 6, a thickness of the graphene layer is 0.35-20 nm;

in step 6, the graphene layer is formed by low-temp chemical vapor deposition graphene coating with hydrocarbons as a source of carbon;

process conditions of the chemical vapor deposition are: the pressure is 5 Pa-5 kPa, and the temperature is 400-680 degrees Celsius;

in step 7, the etching to the graphene layer is implemented by laser etching or dry etching;

the positions of the metal film array and the graphene layer array are located near a channel.

The benefits of the present invention are: in the method of defining poly-silicon growth direction according to the present invention, the metal film array and the graphene layer array are formed in the ELA process. With the excellent thermal conductivities of the metal film and the graphene layer, the temperature of the area of the metal film array and the graphene layer array is lower. Accordingly, temperature gradients exist among respective areas when the amorphous silicon is re-crystallized. The amorphous silicon starts growing and becomes larger from a low temperature area comprising the metal film array and the graphene layer array toward high temperature areas around to form poly-silicon. The method is feasible and capable of defining and controlling the growth direction of the poly-silicon as being formed. The grain size of the poly-silicon can be increased. Accordingly, the electron mobility of the poly-silicon is promoted and the response rate of the flat panel display can be raised.

### BRIEF DESCRIPTION OF THE DRAWINGS

The technical solution, as well as beneficial advantages, of the present invention will be apparent from the following detailed description of an embodiment of the present invention, with reference to the attached drawings.

In drawings,

FIG. 1 is a flowchart of a method of defining poly-silicon growth direction according to the present invention;

FIG. 2 is a diagram of step 3 according to the according to the present invention of the present invention;

FIG. 3 is a diagram of step 4 according to the according to the present invention of the present invention;

FIG. 4 is a diagram of step 5 according to the according to the present invention of the present invention;

FIG. 5 is a diagram of step 6 according to the according to the present invention of the present invention;

FIG. 6 is a diagram of step 7 according to the according to the present invention of the present invention;

FIG. 7 is a diagram of step 10 according to the according to the present invention of the present invention;

FIG. 8 is a diagram of step 11 according to the according to the present invention of the present invention.

### DETAILED DESCRIPTION OF PREFERRED EMBODIMENTS

Embodiments of the present invention are described in detail with the technical matters, structural features, achieved objects, and effects with reference to the accompanying drawings as follows.

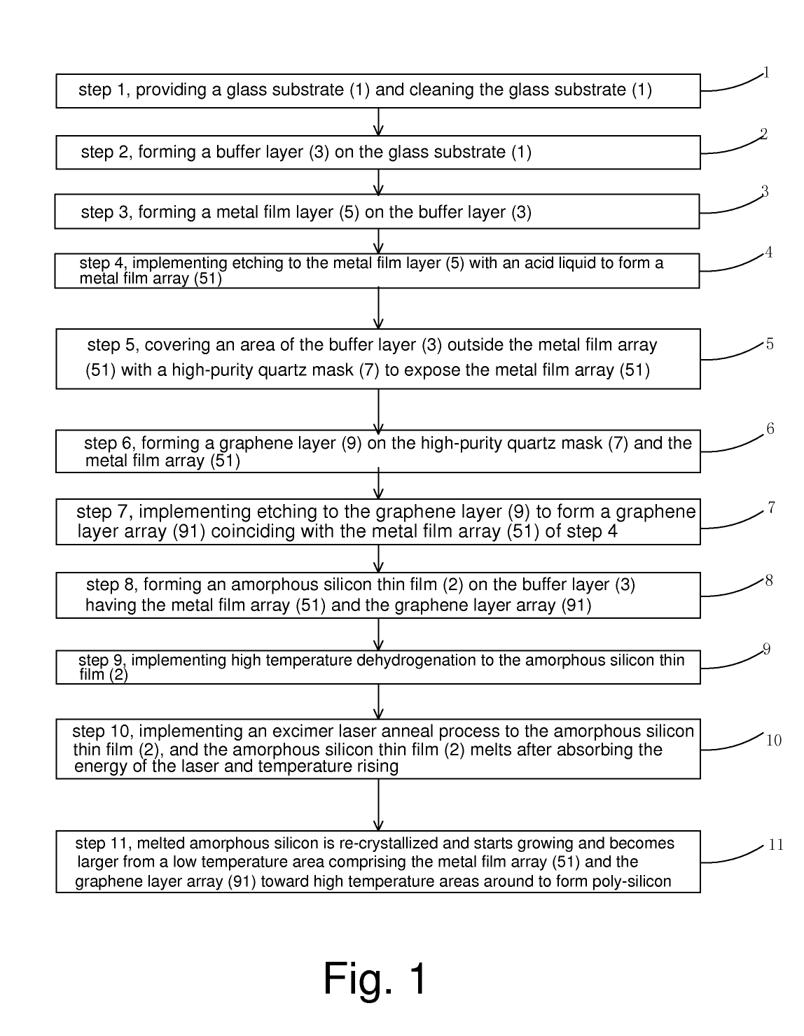

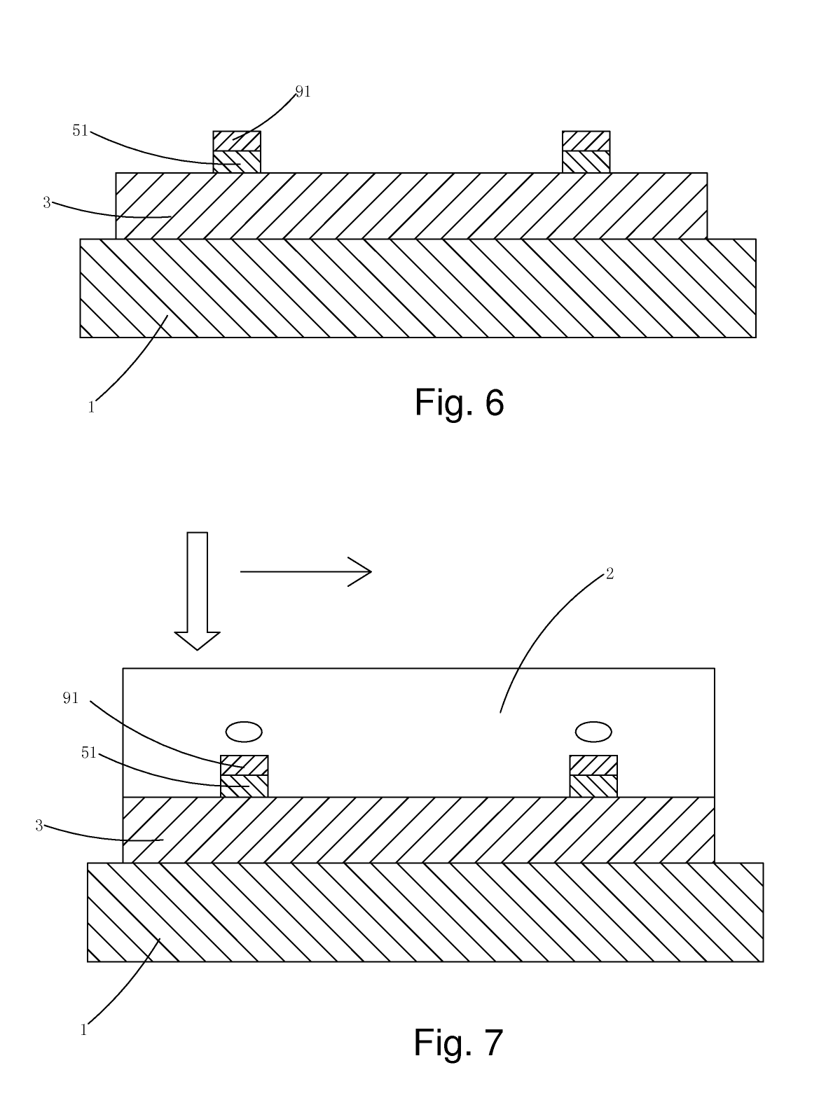

Please refer from FIG. 1 to FIG. 8. The present invention provides a method of defining poly-silicon growth direction, comprising steps of:

step 1, providing a glass substrate 1 and cleaning the glass substrate 1.

step 2, forming a buffer layer 3 on the glass substrate 1.

Specifically, buffer layer 3 comprises two portions, one portion near the glass substrate 1 is amorphous silicon nitride SiNx, and the other portion relatively far from the glass substrate 1 is silicon oxide SiOx, and the SiOx is on the SiNx.

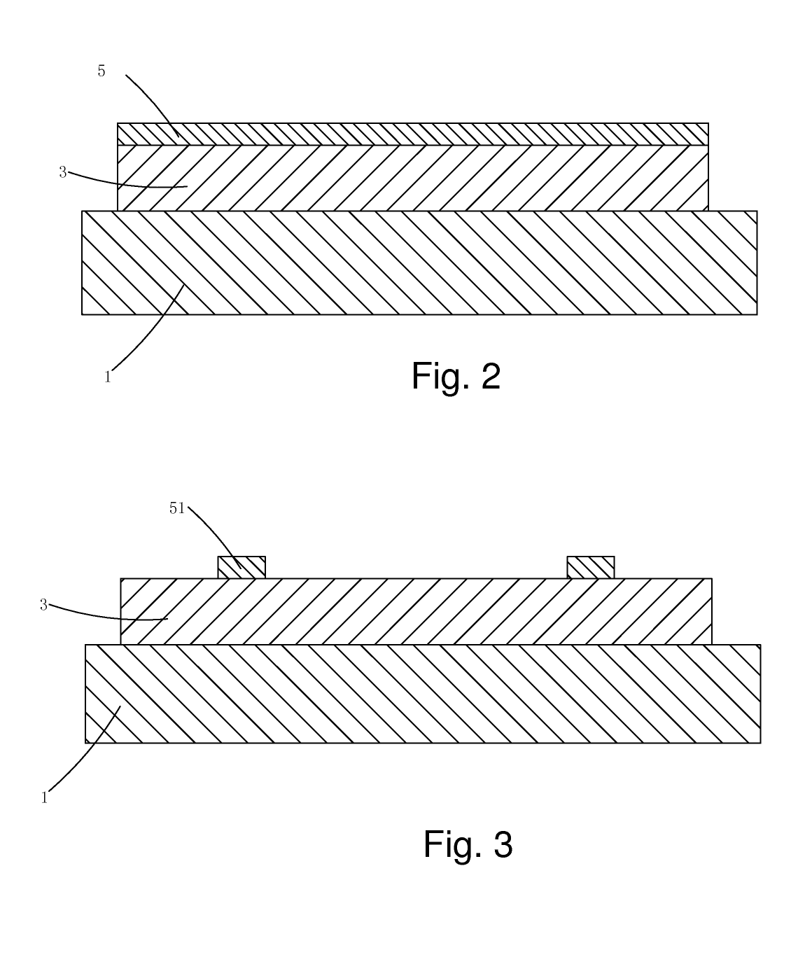

step 3, as shown in FIG. 2, forming a metal film layer 5 on the buffer layer 3.

Specifically, in step 3, one or more of copper Cu, nickel Ni, gold Au, platinum Pt, iron Fe, molybdenum Mo, aluminum Al with the purity≧99.9% is employed as the material. Preferably, copper Cu can be employed as the material. The metal film layer 5 is formed by PVD physical vapor deposition metal coating. The thickness of the metal film layer 5 is 10-500 nm.

step 4, as shown in FIG. 3, implementing etching to the metal film layer 5 with an acid liquid to form a metal film array 51.

Preferably, cuprate is employed to etch the copper film layer 51.

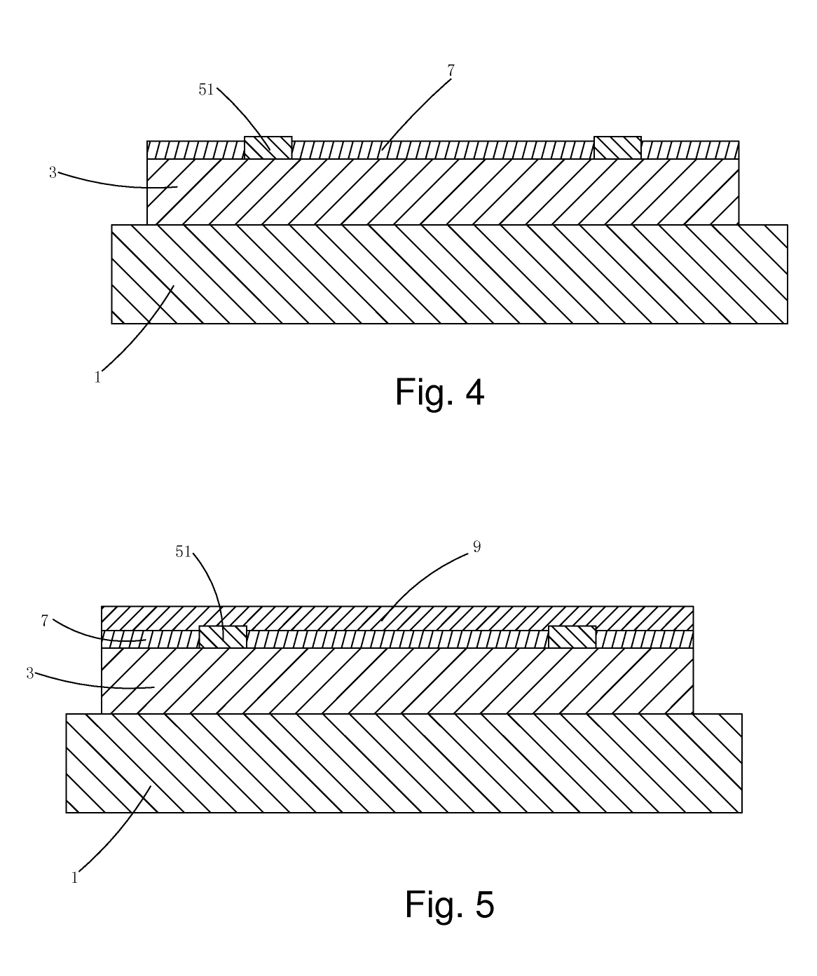

step 5, as shown in FIG. 4, covering an area of the buffer layer 3 outside the metal film array 51 with a high-purity quartz mask 7 to expose the metal film array 51.

step 6, as shown in FIG. 5, forming a graphene layer 9 on the high-purity quartz mask 7 and the metal film array 51.

Specifically, in step 6, hydrocarbons are employed as a source of carbon. Low-temp chemical vapor deposition graphene coating is employed for coating the graphene with process conditions, pressure of 5 Pa-5 kPa and temperature of 400-680 degrees Celsius to form the graphene layer 9. The graphene is a new material which is composed by carbon atoms with a single sheet structure and has excellent thermal conductivity. The coefficient of thermal conductivity can be reaching up to 5300 W/m·K. The thickness of graphene layer 9 is 0.35-20 nm.

step 7, implementing etching to the graphene layer 9 to form a graphene layer array 91 coinciding with the metal film array 51 of step 4.

Specifically, in step 7, the etching to the graphene layer 9 is implemented by laser etching or dry etching. Meanwhile, the quartz mask 7 covering an area of the buffer layer outside the metal film array 51 is etched to expose the buffer layer 3.

step 8, forming an amorphous silicon thin film 2 on the buffer layer 3 having the metal film array 51 and the graphene layer array 91.

step 9, implementing high temperature dehydrogenation to the amorphous silicon thin film 2.

step 10, as shown in FIG. 7, implementing an Excimer laser anneal process to the amorphous silicon thin film 2, and the amorphous silicon thin film 2 melts after absorbing the energy of the laser and temperature rising.

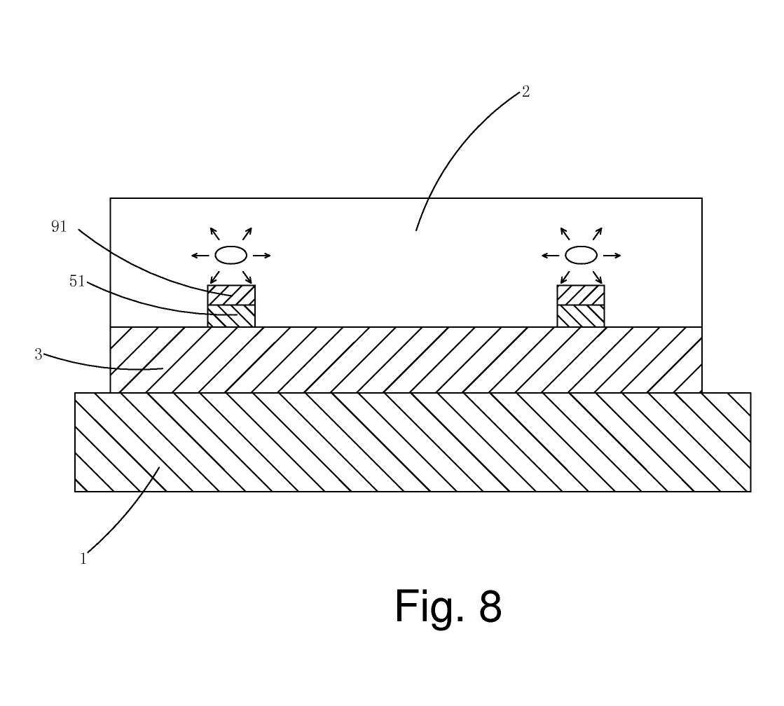

step 11, as shown in FIG. 8, melted amorphous silicon is re-crystallized and starts growing and becomes larger from a low temperature area comprising the metal film array 51 and the graphene layer array 91 toward high temperature areas around to form poly-silicon.

Due to the excellent thermal conductivities of the metal film and the graphene layer, in comparison with the area outside the metal film array 51 and the graphene layer array 91, the heat radiation is faster and the temperature is lower in the area of the metal film array 51 and the graphene layer array 91. Accordingly, temperature gradients exist among respective areas when the amorphous silicon thin film 2 is re-crystallized. The re-crystallization occurs in accordance with the directions from low energy toward high energy, from low temperature to high temperature. The grain sizes of the low temperature poly-silicon increase after the re-crystallization.

Significantly, the positions of the metal film array 51 and the graphene layer array 91 are located near a channel. The channel means a conducting layer along a length direction introduced by an external electric field. By positioning the metal film array 51 and the graphene layer array 91 nearby, the channel can be one grain as far as possible. It is beneficial to promote the electron mobility of the low temperature poly-silicon.

In conclusion, in the method of defining poly-silicon growth direction according to the present invention, the metal film array and the graphene layer array are formed in the ELA process. With the excellent thermal conductivities of the metal film and the graphene layer, the temperature of the area of the metal film array and the graphene layer array is lower. Accordingly, temperature gradients exist among respective areas when the amorphous silicon is re-crystallized. The amorphous silicon starts growing and becomes larger from a low temperature area comprising the metal film array and the graphene layer array toward high temperature areas around to form poly-silicon. The method is feasible and capable of defining and controlling the growth direction of the poly-silicon as being formed. The grain size of the poly-silicon can be increased. Accordingly, the electron mobility of the poly-silicon is promoted and the response rate of the flat panel display can be raised.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A method of defining poly-silicon growth direction, comprising steps of:
step 1, providing a glass substrate and cleaning the glass substrate;
step 2, forming a buffer layer on the glass substrate;
step 3, forming a metal film layer on the buffer layer;
step 4, implementing etching to the metal film layer with an acid liquid to form a metal film array;
step 5, covering an area of the buffer layer outside the metal film array with a high-purity quartz mask to expose the metal film array;
step 6, forming a graphene layer on the high-purity quartz mask and the metal film array;
step 7, implementing etching to the graphene layer to form a graphene layer array coinciding with the metal film array of the fourth step;
step 8, forming an amorphous silicon thin film on the buffer layer having the metal film array and the graphene layer array;
step 9, implementing high temperature dehydrogenation to the amorphous silicon thin film;
step 10, implementing an Excimer laser anneal process to the amorphous silicon thin film, and the amorphous silicon thin film melts after absorbing the energy of the laser and temperature rising;
step 11, melted amorphous silicon is re-crystallized and starts growing and becomes larger from a low temperature area comprising the metal film array and the graphene layer array toward high temperature areas around to form poly-silicon.

2. The method of defining poly-silicon growth direction according to claim 1, wherein the buffer layer in the second step comprises two portions, one portion near the glass substrate is amorphous silicon nitride SiNx, and the other portion relatively far from the glass substrate is silicon oxide SiOx, and the SiOx is on the SiNx.

3. The method of defining poly-silicon growth direction according to claim 1, wherein the metal film layer in the third step is formed by physical vapor deposition metal coating.

4. The method of defining poly-silicon growth direction according to claim 1, wherein a thickness of the metal film layer in the third step is 10-500 nm.

5. The method of defining poly-silicon growth direction according to claim 4, wherein a material of the metal film layer is one or more of copper Cu, nickel Ni, gold Au, platinum Pt, iron Fe, molybdenum Mo, aluminum Al, and the purity≧99.9%.

6. The method of defining poly-silicon growth direction according to claim 1, wherein in the sixth step, a thickness of the graphene layer is 0.35-20 nm.

7. The method of defining poly-silicon growth direction according to claim 1, wherein in the sixth step, the graphene layer is formed by low-temp chemical vapor deposition graphene coating with hydrocarbons as a source of carbon.

8. The method of defining poly-silicon growth direction according to claim 7, wherein process conditions of the chemical vapor deposition are: the pressure is 5 Pa-5 kPa, and the temperature is 400-680 degrees Celsius.

9. The method of defining poly-silicon growth direction according to claim 1, wherein in the seventh step, the etching to the graphene layer is implemented by laser etching or dry etching.

10. The method of defining poly-silicon growth direction according to claim 1, wherein the positions of the metal film array and the graphene layer array are located near a channel.

11. A method of defining poly-silicon growth direction, comprising steps of:
step 1, providing a glass substrate and cleaning the glass substrate;
step 2, forming a buffer layer on the glass substrate;
step 3, forming a metal film layer on the buffer layer;
step 4, implementing etching to the metal film layer with an acid liquid to form a metal film array;
step 5, covering an area of the buffer layer outside the metal film array with a high-purity quartz mask to expose the metal film array;
step 6, forming a graphene layer on the high-purity quartz mask and the metal film array;
step 7, implementing etching to the graphene layer to form a graphene layer array coinciding with the metal film array of the fourth step;
step 8, forming an amorphous silicon thin film on the buffer layer having the metal film array and the graphene layer array;
step 9, implementing high temperature dehydrogenation to the amorphous silicon thin film;
step 10, implementing an Excimer laser anneal process to the amorphous silicon thin film, and the amorphous silicon thin film melts after absorbing the energy of the laser and temperature rising;
step 11, melted amorphous silicon is re-crystallized and starts growing and becomes larger from a low temperature area comprising the metal film array and the graphene layer array toward high temperature areas around to form poly-silicon;
wherein the buffer layer in the second step comprises two portions, one portion near the glass substrate is amorphous silicon nitride SiNx, and the other portion relatively far from the glass substrate is silicon oxide SiOx, and the SiOx is on the SiNx;
wherein the metal film layer in the third step is formed by physical vapor deposition metal coating;
wherein a thickness of the metal film layer in the third step is 10-500 nm;
wherein a material of the metal film layer is one or more of copper Cu, nickel Ni, gold Au, platinum Pt, iron Fe, molybdenum Mo, aluminum Al, and the purity≧99.9%;
wherein in the sixth step, a thickness of the graphene layer is 0.35-20 nm;
wherein in the sixth step, the graphene layer is formed by low-temp chemical vapor deposition graphene coating with hydrocarbons as a source of carbon;
wherein process conditions of the chemical vapor deposition are: the pressure is 5 Pa-5 kPa, and the temperature is 400-680 degrees Celsius;
wherein in the seventh step, the etching to the graphene layer is implemented by laser etching or dry etching;
wherein the positions of the metal film array and the graphene layer array are located near a channel.
